(19) United States
(12) Patent Application Publication
(10) Pub. No.: US 2024/0356316 A1
(43) Pub. Date: Oct. 24, 2024

(54) ELECTRICAL JUNCTION BOX

(71) Applicant: SUMITOMO WIRING SYSTEMS, LTD., Mie (JP)

(72) Inventor: Shunsuke KATSUSE, Mie (JP)

(21) Appl. No.: 18/285,626

(22) PCT Filed: Mar. 17, 2022
(86) PCT No.: PCT/JP2022/012356

§ 371 Date: Oct. 4, 2023

(30) Foreign Application Priority Data
Apr. 9, 2021 (JP) 2021-066190

(51) Int. Cl. H02G 3/08

(52) U.S. Cl. CPC H02G 3/081

(57) ABSTRACT

An object of the present disclosure is to achieve both an increase in the workability of assembling a busbar and the reliability of the function for holding an assembled state. An electrical junction box (A) includes a base member (10) that has a component housing chamber (12) and a side wall member (11) that is a separate member from the base member (10) and is assembled to the base member (10). The side wall member (11) has a side wall main body (40) in which a busbar housing chamber (44) is formed and a busbar (55) that is inserted into the busbar housing chamber (44). The base member (10) has a detachment restriction part (26) that restricts the busbar (55) from being detached to the outside of the busbar housing chamber (44).

### TECHNICAL FIELD

The present disclosure relates to an electrical junction box.

### BACKGROUND

Patent Document 1 discloses an electrical junction box in which a busbar is attached to a resin electronic component block. In attaching the busbar to the electronic component block, a surface press jig is used to push the busbar into a busbar assembly part of the electronic component block.

### PRIOR ART DOCUMENT

### Patent Document

Patent Document 1: JP 2020-080587A

### SUMMARY OF THE INVENTION

### Problems to be Solved

The above-described electrical junction box has poor workability because the more the surface press jig is needed, the stronger the busbar needs to be pushed into the busbar assembly part. In order to increase the workability, it may be sufficient to reduce the resistance to assembling of the busbar. However, if the resistance is decreased, the busbar is likely to come loose, and the reliability of the function of holding the electrical junction box in the assembled state will be reduced. That is, in the busbar assembly structure of a conventional electrical junction box, it is difficult to achieve both an improvement in the workability of assembly and the reliability of the function for holding the assembled state because there is a trade-off between the two.

An electrical junction box of the present disclosure is completed in view of the foregoing circumstances. An object of the present disclosure is to achieve both an increase in the workability of assembling a busbar and the reliability of the function for holding the assembled state.

### Means to Solve the Problem

An electrical junction box of the present disclosure includes:
a base member that has a component housing chamber; and
a side wall member that is a separate member from the base member and is assembled to the base member,
wherein the side wall member has a side wall main body in which a busbar housing chamber is formed and a busbar that is inserted into the busbar housing chamber, and
the base member has a detachment restriction part that restricts the busbar from being detached to the outside of the busbar housing chamber.

### Effect of the Invention

According to the present disclosure, it is possible to achieve both an increase in the workability of assembling a busbar and the reliability of the function for holding the assembled state.

### BRIEF DESCRIPTION OF THE DRAWINGS

FIG. 1 is a perspective view of an electrical junction box in Embodiment 1.

FIG. 2 is a perspective view of a base member.

FIG. 3 is a perspective diagram showing a state where each side wall member is separated into a side wall main body and a busbar.

FIG. 4 is a bottom view of the electrical junction box.

FIG. 5 is a front cross-sectional view of the electrical junction box.

### DETAILED DESCRIPTION TO EXECUTE THE INVENTION

### Description of Embodiments of the Present Disclosure

First, embodiments of the present disclosure will be listed and described.

(1) An electrical junction box of the present disclosure includes: a base member that has a component housing chamber; and a side wall member that is a separate member from the base member and is assembled to the base member. The side wall member has a side wall main body in which a busbar housing chamber is formed and a busbar that is inserted into the busbar housing chamber. The base member has a detachment restriction part that restricts the busbar from being detached to the outside of the busbar housing chamber. According to the electrical junction box of the present disclosure, even if the resistance to insertion of the busbar into the busbar housing chamber is reduced, the busbar is held in the state of being housed in the busbar housing chamber by the detachment restriction part. Therefore, according to the present disclosure, it is possible to achieve both an increase in the workability of assembling the busbar and the reliability of the function for holding the busbar in the assembled state.

(2) The side wall main body preferably has a busbar attachment port for inserting the busbar into the busbar housing chamber, and the detachment restriction part is preferably disposed so as to cover the busbar attachment port. This configuration eliminates the need to provide the side wall main body with a portion for fitting the detachment restriction part. Accordingly, it is possible to avoid an increase in the complexity of the shape of the side wall main body due to the provision of the detachment restriction part.

(3) According to (2), the detachment restriction part preferably has a communication hole that brings the inside of the busbar housing chamber into communication with the outside of the side wall main body. According to this configuration, it is possible to release heat generated by the busbar to the outside of the busbar housing chamber through the communication hole.

(4) According to (2) or (3), a front end portion of the busbar is preferably provided with a connection plate part that is fixed to a connection member provided in the base member, the detachment restriction part is preferably disposed so as to support only a back end portion of the busbar, and a central portion of the busbar in a front-back direction is preferably exposed to the outside of the side wall main body through the busbar attachment port. According to this configuration, it is possible to stably hold the busbar at two front and back places and efficiently release heat from the busbar to the outside of the side wall main body.

(5) According to (2) to (4), the busbar housing chamber is preferably defined by an outer wall part that constitutes an outer surface of the side wall main body and an inner wall part that is positioned between the outer wall part and the base member, and the detachment restriction part preferably has a hook part that hooks on the inner wall part from the outside at the busbar attachment port. According to this configuration, since the hook part hooks on the inner wall part, it is possible to prevent the side wall member from being detached from the base member.

### Details of Embodiments of Present Disclosure

### Embodiment 1

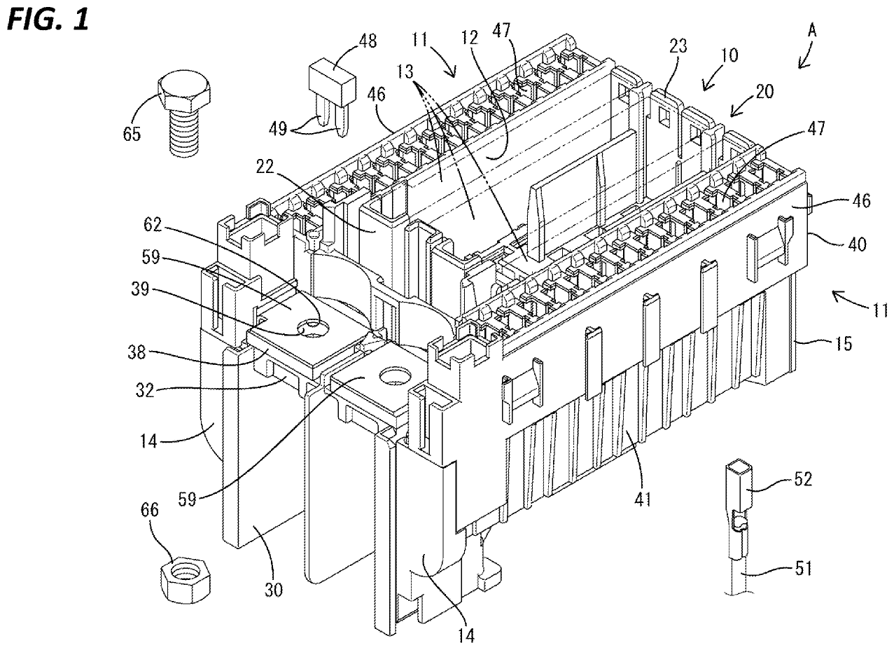

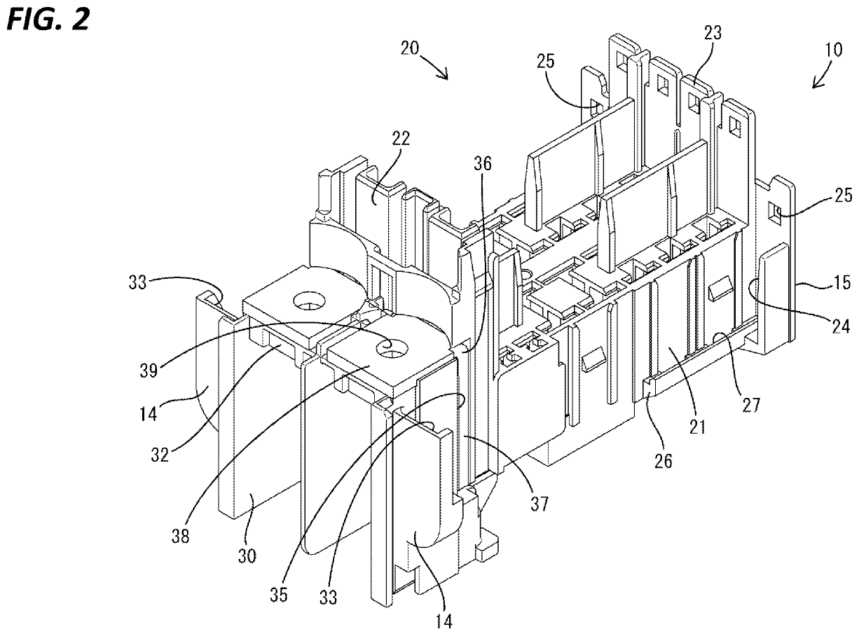

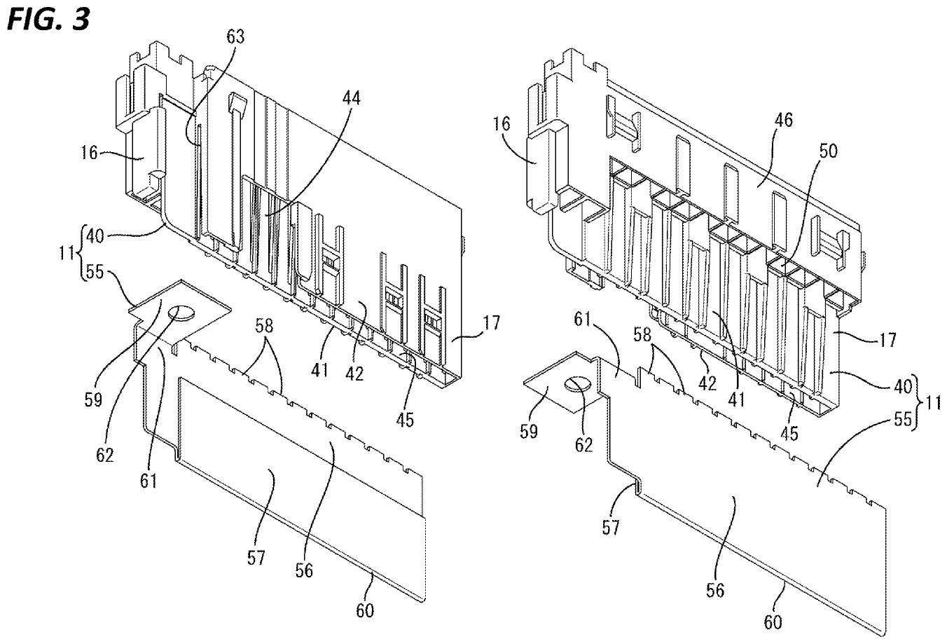

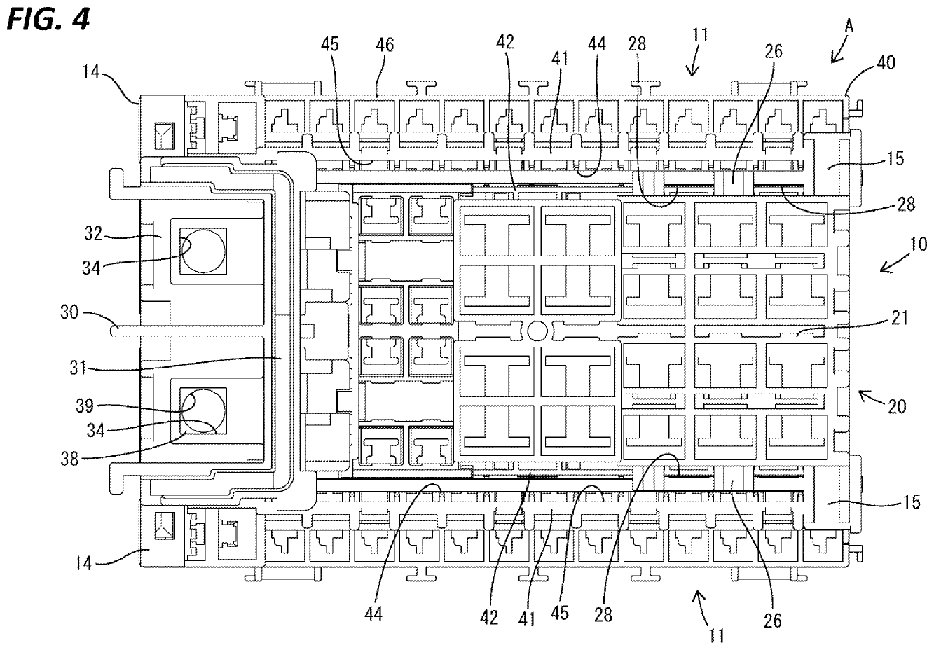

Embodiment 1 in which the electrical junction box of the present disclosure is embodied will be described with reference to FIGS. 1 to 5. It should be noted that the present invention is not limited to the examples herein, but rather is indicated by the scope of the claims, and is intended to include all modified examples within a meaning and scope equivalent to the scope of claims. In Embodiment 1, as for the front-back direction of an electrical junction box A, the direction extending obliquely downward and to the left in FIGS. 1 and 2, the direction extending obliquely upward and to the left in FIG. 3, and the leftward direction in FIG. 4 are defined as the forward direction. As for the vertical direction of the electrical junction box A, the upward and downward directions shown in FIGS. 1 to 3 and 5 will be defined as upward and downward directions as they are. As for the horizontal direction of an electrical junction box A, the rightward and leftward directions shown in FIG. 4 will be defined as rightward and leftward directions as they are.

### Overview of Electrical Junction Box A

As shown in FIGS. 1 and 4, the electrical junction box A in Embodiment 1 includes one base member 10 and a pair of left-right symmetrical side wall members 11 that are separate members from the base member 10. The pair of side wall members 11 are assembled to the base member 10 so as to sandwich the base member 10 from left and right sides. The electrical junction box A has a component housing chamber 12 that is defined by the base member 10 and the pair of side wall members 11. The component housing chamber 12 is open on the upper surface of the electrical junction box A. The component housing chamber 12 houses a plurality of electrical components 13 such as fusible links.

A pair of left and right front-side fitting parts 14 are respectively provided on front end portions of the base member 10, and a pair of left and right back-side fitting parts 15 are respectively provided on back end portions of the base member 10. As shown in FIG. 3, a pair of left and right front-side fit-in parts 16 are respectively provided on front end portions of the side wall members 11, and a pair of left and right back-side fit-in parts 17 are respectively provided on back end portions of the side wall members 11. When the front-side fitting parts 14 and the front-side fit-in parts 16 are fitted to each other and the back-side fitting parts 15 and the back-side fit-in parts 17 are fitted to each other, the base member 10 and the side wall members 11 are held in the assembled state.

### Base Member 10

The base member 10 includes a holding member 20 made of a synthetic resin, a terminal block 30 made of a synthetic resin and that is a separate component from the holding member 20, and plates 36 that form a pair of left-right symmetrical connection members. As shown in FIG. 2, the holding member 20 is a single component that has a main body part 21 that has a rectangular parallelepiped shape whose long sides are oriented in the front-back direction, a front plate part 22 that extends upward from the front edge of the main body part 21, and a back plate part 23 that extends upward from the back edge of the main body part 21. The space surrounded by the upper surface of the main body part 21, the back surface of the front plate part 22, and the front surface of the back plate part 23 functions as the component housing chamber 12. When the side wall members 11 are not assembled to the base member 10, the component housing chamber 12 is open to outside of the base member 10 on the upper surface of the base member 10 and the left and right side surfaces of the base member 10.

The pair of left-right symmetrical back-side fitting parts 15 are provided at the left and right end portions of the back plate part 23. Each back-side fitting part 15 has a guide groove 24 that is elongated in the vertical direction is are open forward and upward. Each back-side fitting part 15 has an engagement hole 25 that extends through the back-side fitting part 15 in the front-back direction and is in communication with the guide groove 24.

As shown in FIGS. 2, 4, and 5, the main body part 21 has a pair of left-right symmetrical detachment restriction parts 26. The detachment restriction parts 26 are elongated in the front-back direction and protrude outward in the horizontal direction from lower edges of the outer surface of the main body part 21. The formation area of the detachment restriction parts 26 in the front-back direction is located only at the back end portion (back end-side area) of the main body part 21. Each detachment restriction part 26 has a rib-like hook part 27 protruding upward at the protruding edge thereof. Each detachment restriction part 26 has a plurality of communication holes 28 spaced apart from each other in the front-back direction between the main body part 21 and the hook part 27. The communication holes 28 extend through the detachment restriction part 26 in the vertical direction.

The terminal block 30 is a single component that has a support plate part 31 whose thickness direction is oriented in the front-back direction (see FIG. 4) and a receiving plate part 32 whose thickness direction is oriented in the vertical direction. The pair of left-right symmetrical front-side fitting parts 14 are formed at the left and right end portions of the terminal block 30. Each front-side fitting part 14 has a vertical groove part 33 (see FIG. 2) open upward and backward on the back surface thereof. The receiving plate part 32 has bolt holes 34 extending vertically therethrough (see FIG. 4). The terminal block 30 is assembled to the holding member 20 so as to cover the front surface of the front plate part 22. There is a pair of left and right housing spaces 35 (see FIG. 2) between the front plate part 22 and the support plate part 31.

As shown in FIG. 2, each plate 36 is a single component that has a plate-like power supply part 37 and a plate-like attachment part 38 connected to each other at a right angle. The plate-like power supply part 37 has a flat-plate shape whose thickness direction is oriented in the front-back direction. The plate-like attachment part 38 has a flat-plate shape whose thickness direction is oriented in the vertical direction, and extends forward from the upper edge of the plate-like power supply part 37. The plate-like attachment part 38 has an attachment hole 39. Each plate 36 is assembled to the base member 10 in a state where the plate-like power supply part 37 is housed in a housing space 35 and the plate-like attachment part 38 is placed on the receiving plate part 32. The plate-like power supply part 37 is connected to a power supply terminal (not shown) connected to a battery (not shown).

### Side Wall Members 11

Each side wall member 11 is formed by assembling a side wall main body 40 made of a synthetic resin and a metallic busbar 55. As shown in FIGS. 1 and 3, the side wall main body 40 is a single component that is elongated in the front-back direction in a plan view and whose thickness direction is oriented in the horizontal direction. As shown in FIGS. 3 to 5, the side wall main body 40 has an outer wall part 41 whose thickness direction is oriented in the horizontal direction and an inner wall part 42 whose thickness direction is oriented in the horizontal direction. A lower end-side portion of the front edge part of each side wall main body 40 functions as the front-side fit-in part 16. A lower end-side portion of the back edge part of each side wall main body 40 functions as the back-side fit-in part 17. The side wall main body 40 has a protrusion-like engagement protrusion (not shown) formed on the back end surface thereof.

The side wall main body 40 internally has one busbar housing chamber 44 sandwiched between the outer wall part 41 and the inner wall part 42. The busbar housing chamber 44 is a narrow space whose horizontal length is smaller than the front-back length and the vertical length. The lower end of the busbar housing chamber 44 is open on the lower surface of the side wall main body 40, as a busbar attachment port 45 that has a slit-like shape extending in the front-back direction. The busbar attachment port 45 is an opening for attaching the busbar 55 to the busbar housing chamber 44.

As shown in FIG. 1, the side wall main body 40 has a wide part 46 at the upper end portion thereof, which is wider than the lower end-side area of the side wall main body 40. The wide part 46 internally has a plurality of fuse housing chambers 47 that are open on the upper surface of the side wall main body 40 and are aligned in a line in the front-back direction. The lower end portions of the plurality of fuse housing chambers 47 are in communication with the busbar housing chamber 44. Fuses 48 are attached to the fuse housing chambers 47 from above the side wall members 11. One lead 49 of each fuse 48 is connected to a tab 58 of the busbar 55. As shown in FIG. 3, in the lower end-side area of the wide part 46, a plurality of cavities 50 open on the lower surface of the side wall main body 40 are arranged in a line in the front-back direction. The upper ends of the plurality of cavities 50 are individually in communication with the lower ends of the plurality of fuse housing chambers 47. The cavities 50 house harness terminals 52 individually connected to a plurality of electrical wires 51. Each harness terminal 52 is connected to the other lead 49 of the corresponding fuse 48.

Each busbar 55 is a single component that is formed by bending a metallic flat plate that has been stamped into a predetermined shape. As shown in FIG. 3, the busbar 55 has one flat plate-like substrate part 56 whose thickness direction is oriented in the horizontal direction, one flat plate-like heat dissipation part 57, a plurality of tabs 58, and one flat plate-like connection plate part 59. The substrate part 56 and the heat dissipation part 57 form a rectangular shape as seen in a side view of the busbar 55 from the horizontal direction. The heat dissipation part 57 is disposed so as to overlap the inner surface of the substrate part 56. The lower edge of the substrate part 56 and the lower edge of the heat dissipation part 57 are connected to each other via a bent part 60 with a U-shaped cross section. The plurality of tabs 58 protrude upward from the upper edge of the substrate part 56 and are arranged spaced apart from each other in the front-back direction. The connection plate part 59 protrudes inward in the horizontal direction from the upper edge of a support part 61 at the front end portion of the substrate part 56. The connection plate part 59 has a through hole 62 extending therethrough in the vertical direction.

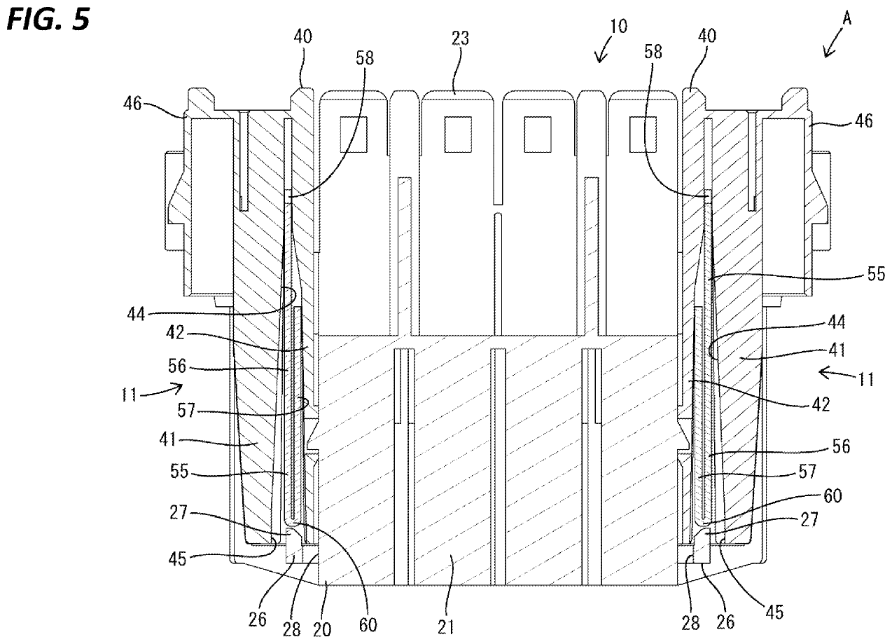

The busbar 55 is assembled to the side wall main body 40 from below. Specifically, the substrate part 56, the heat dissipation part 57, and the tabs 58 are housed in the busbar housing chamber 44 via the busbar attachment port 45. The connection plate part 59 protrudes from a cutout part 63 of the inner wall part 42 toward the outside of the side wall main body 40. The connection plate part 59 protrudes inward past the side wall main body 40, that is, toward the base member 10 in the horizontal direction. As shown in FIG. 5, the bent part 60 at the lower edge of the busbar 55 is positioned near the busbar attachment port 45. That is, the bent part 60 is positioned so as to be easily seen from the busbar attachment port 45.

### Procedure of Assembling Electrical Junction Box A

In assembling the electrical junction box A, while the holding member 20 and the terminal block 30 are separated from each other, the plate-like attachment parts 38 of the plates 36 are placed on the receiving plate part 32, and the plate-like power supply parts 37 are overlaid on the back surface of the terminal block 30. In this state, when the terminal block 30 and the plates 36 are assembled, the housing spaces 35 are formed and the plate-like power supply parts 37 of the plates 36 are housed in the housing spaces 35, whereby the base member 10 is completely assembled.

After assembling the base member 10, the electrical components 13 are attached to the holding member 20 so as to be housed in the component housing chamber 12 from above the base member 10. Since the component housing chamber 12 is open to the left and right sides of the base member 10, provided a worker attaches an electrical component 13 while pinching it from the left and right sides, the worker's fingers pinching the electrical component 13 will not interfere with the base member 10. In the case of attaching the electrical components 13 using an automated instrument, similarly, the automated instrument sandwiches the electrical component 13 in its fingers from the left and right sides so that the fingers do not interfere with the base member 10.

Next, the pair of side wall members 11 are assembled to the base member 10. At the time of assembly, the front-side fit-in parts 16 are inserted and fitted into the groove parts 33 of the front-side fitting parts 14 from above, and the back-side fit-in parts 17 are inserted and fitted into the guide grooves 24 of the back-side fitting parts 15 from above. When the side wall members 11 are assembled in a predetermined state to the base member 10, engagement protrusions (not shown) of the side wall members 11 engage with the engagement holes 25. When the front-side fit-in parts 16 are fitted to the front-side fitting parts 14, the side wall members 11 are positioned with respect to the base member 10 in the front-back direction and the horizontal direction. The engagement of the engagement protrusions (not shown) and the engagement holes 25 restricts upward detachment of the side wall members 11 from the base member 10.

When the side wall members 11 are attached to the base member 10, the component housing chamber 12 is covered by the side wall members 11 from the left and right sides, whereby the electrical junction box A is completely assembled. The component housing chamber 12 is surrounded over the entire circumference in the front-back direction and the horizontal direction. The connection plate part 59 of each busbar 55 is laid on the upper surface of the plate-like attachment part 38 of the corresponding plate 36. When bolts 65 are inserted into the through holes 62, the attachment holes 39, and the bolt holes 34 and screwed into nuts 66 on the lower surface of the receiving plate part 32, the plate 36 and the busbar 55 are fixed to the terminal block 30. When the connection plate parts 59 are fixed to the receiving plate part 32, the front end portions of the side wall members 11 are fixed to the front end portion of the base member 10.

In the state where the side wall members 11 are attached to the base member 10, only the back end portions of the lower surfaces of the side wall members 11 are covered by the detachment restriction parts 26 from below. The detachment restriction parts 26 cover only the back end portions of the opening areas of the busbar attachment ports 45. Since the forward sides of the opening areas of the busbar attachment ports 45 past the detachment restriction parts 26 are open without being covered by the detachment restriction parts 26, heat from the busbars 55 and heat in the busbar housing chambers 44 is released from the busbar attachment ports 45 to the outside of the side wall main bodies 40. Since the detachment restriction parts 26 have the plurality of communication holes 28, heat from the busbars 55 and heat in the busbar housing chambers 44 is also released to the outside of the side wall main bodies 40 through the communication holes 28.

The hook part 27 slightly enters the busbar housing chamber 44 through the busbar attachment port 45 and enters a state of abutment with the bent part 60 of the busbar 55 from below or approaches the bent part 60 of the busbar 55 from below and enters a state of facing the bent part 60. Accordingly, even if the busbar 55 acts to detach downward from the side wall main body 40, the bent part 60 abuts against the hook part 27 so that the busbar 55 is not detached from the side wall main body 40 and is held in the busbar housing chamber 44. The hook part 27 engages with the inner wall part 42 of the side wall main body 40 from the inner side, that is, from the side opposite to the base member 10. This engagement restricts the detachment of the side wall member 11 from the base member 10 in the horizontal direction.

### Operations and Advantageous Effects of Embodiment

The electrical junction box A in the present embodiment includes the base member 10 having the component housing chamber 12 and the side wall members 11 that are separate members from the base member 10 and are assembled to the base member 10. Each side wall member 11 has the side wall main body 40 in which the busbar housing chamber 44 is formed and the busbar 55 that is inserted into the busbar housing chamber 44. The base member 10 has the detachment restriction part 26 that restricts the busbar 55 from being detached to the outside of the busbar housing chamber 44. According to this configuration, even if resistance to insertion of the busbar 55 into the busbar housing chamber 44 is reduced, the busbar 55 can be held in the state of being housed in the busbar housing chamber 44 by the detachment restriction part 26. Therefore, the electrical junction box A of the present embodiment achieves both an increase in the workability of assembling the busbar 55 and the reliability of the function for holding the busbar 55 in the assembled state.

Each side wall main body 40 has the busbar attachment port 45 for inserting the busbar 55 into the busbar housing chamber 44. Each detachment restriction part 26 provided on the base member 10 is arranged so as to cover the corresponding busbar attachment port 45. According to this configuration, since there is no need to form a part in the side wall main body 40 for fitting the detachment restriction part 26, it is possible to avoid an increase in the complexity of the shape of the side wall main body 40 due to the provision of the detachment restriction part 26.

Each detachment restriction part 26 has the communications hole 28 that are in communication with the inside of the busbar housing chamber 44 and the outside of the side wall main body 40. Accordingly, it is possible to release heat generated by the busbar 55 to the outside of the busbar housing chamber 44 through the communication holes 28.

Each busbar 55 has, at the front end portion thereof, the connection plate part 59 that is to be fixed to the plate 36 provided in the base member 10. The detachment restriction part 26 is disposed so as to support only the back end portion of the busbar 55. The center part of the busbar 55 in the front-back direction is exposed to the outside of the side wall main body 40 via the busbar attachment port 45. According to this configuration, it is possible to stably hold the busbar 55 at two front and back places and efficiently release heat from the busbar 55 to the outside of the side wall main body 40.

Each busbar housing chamber 44 is defined by the outer wall part 41 that constitutes the outer surface of the side wall main body 40 and the inner wall part 42 that is positioned between the outer wall part 41 and the base member 10. Each detachment restriction part 26 has the hook part 27 that hooks on the inner wall part 42 from the outside at the busbar attachment port 45. According to this configuration, since the hook part 27 hooks on the inner wall part 42, it is possible to prevent the side wall member 11 from detaching from the base member 10.

### Other Embodiments

The present invention is not limited to the embodiments described above or illustrated in the drawings, but is represented by the scope of the claims. The present invention includes all modifications in the meaning equivalent to the scope of the claims and within the scope of the claims, and further includes embodiments as described below.

In the foregoing embodiment, each detachment restriction part is disposed so as to cover the busbar attachment port. Alternatively, the side wall main body may have a cutout part other than the busbar attachment port so that the detachment restriction part engages with the busbar in the busbar housing chamber via the cutout part.

In the foregoing embodiment, each detachment restriction part has an insertion hole. However, the detachment restriction part may have a shape without an insertion hole.

In the foregoing embodiment, each detachment restriction part is disposed so as to support only the back end portion of the busbar. Alternatively, the detachment restriction part may support only the front end portion of the busbar, only the central part of the busbar in the front-back direction, only the front end portion of the busbar, or the entire area of the busbar from the front end portion to the back end portion.

### LIST OF REFERENCE NUMERALS

A Electrical junction box
10 Base member
11 Side wall member
12 Component housing chamber
13 Electrical component
14 Front-side fitting part
15 Back-side fitting part
16 Front-side fit-in part
17 Back-side fit-in part
20 Holding member
21 Main body part
22 Front plate part
23 Back plate part
24 Guide groove
25 Engagement hole
26 Detachment restriction part
27 Hook part
28 Communication hole
30 Terminal block
31 Support plate part
32 Receiving plate part
33 Groove part
34 Bolt hole
35 Housing space
36 Plate (connection member)
37 Plate-like power supply part
38 Plate-like attachment part
39 Attachment hole
40 Side wall main body
41 Outer wall part
42 Inner wall part
44 Busbar housing chamber
45 Busbar attachment port
46 Wide part
47 Fuse housing chamber
48 Fuse
49 Lead
50 Cavity
51 Electrical wire
52 Harness terminal
55 Busbar
56 Substrate part
57 Heat dissipation part
58 Tab
59 Connection plate part
60 Bent part
61 Support part
62 Through hole
63 Cutout part
65 Bolt
66 Nut

1. An electrical junction box comprising:
a base member that has a component housing chamber; and
a side wall member that is a separate member from the base member and is assembled to the base member,
wherein the side wall member has a side wall main body in which a busbar housing chamber is formed and a busbar that is inserted into the busbar housing chamber, and
the base member has a detachment restriction part that restricts the busbar from being detached to the outside of the busbar housing chamber.

2. The electrical junction box according to claim 1,
wherein the side wall main body has a busbar attachment port for inserting the busbar into the busbar housing chamber, and
the detachment restriction part is disposed so as to cover the busbar attachment port.

3. The electrical junction box according to claim 2,
wherein the detachment restriction part has a communication hole that brings the inside of the busbar housing chamber into communication with the outside of the side wall main body.

4. The electrical junction box according to claim 2,
wherein a front end portion of the busbar is provided with a connection plate part that is fixed to a connection member provided in the base member,
the detachment restriction part is disposed so as to support only a back end portion of the busbar, and
a central portion of the busbar in a front-back direction is exposed to the outside of the side wall main body through the busbar attachment port.

5. The electrical junction box according to claim 2,
wherein the busbar housing chamber is defined by an outer wall part that constitutes an outer surface of the side wall main body and an inner wall part that is positioned between the outer wall part and the base member, and
the detachment restriction part has a hook part that hooks on the inner wall part from the outside at the busbar attachment port.
